(19) United States
(12) Patent Application Publication
(10) Pub. No.: US 2005/0176252 A1
(43) Pub. Date: Aug. 11, 2005

(54) Two-stage load for processing both sides of a wafer

(76) Inventors: Matthew G. Goodman, Chandler, AZ (US); Ravinder Aggarwal, Gilbert, AZ (US); Mark Hawkins, Gilbert, AZ (US); Tony J. Keeton, Mesa, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/775,522

(22) Filed: Feb. 10, 2004

(51) Int. Cl. H01L 21/302; C23C 16/00

(52) U.S. Cl. 438/692; 118/719

(57) ABSTRACT

Disclosed herein is an apparatus and method for treating the frontside and backside of a semiconductor substrate with a process gas. A reactor chamber is equipped with a first load platform configured to permit the access of a process gas to both sides of a substrate. In some embodiments, the apparatus also comprises a second load platform configured for further processing the frontside of the substrate. The substrate is loaded on the first load platform and processed on both sides, then moved to the second load platform and processed on one side.

### BACKGROUND OF THE INVENTION

1. Field of the Invention

The present invention relates to the manufacture semiconductor devices, and, in particular, to processing the frontside and backside of a substrate used in the fabrication of an integrated device, and for apparatuses therefor.

2. Description of the Related Art

A method of obtaining the desired flat and parallel surfaces for silicon wafers used in the fabrication of integrated devices is double-side polishing (DSP), typically, using a chemical mechanical planarization (CMP) process. DSP wafers can have extremely low total thickness variation (TTV), which can improve process uniformity. Certain processes specify wafers with frontsides that are flat to within tenths of a micron or better, thereby placing stringent requirements on the starting wafer flatness.

Multiple CMP stages are often required, starting with one or more rough stock removal steps and ending with a finish polish step in which very little material is removed. Double-side polishing (DSP) provides the flatness levels required as feature sizes continue to decrease. Cosmetic defects, for example, scratches, smudges, and halos, are easier to recognize on the backsides of DSP wafers. Furthermore, the polished backsides of DSP wafers reduce slip sensibility and particle transfer probability.

Surfaces of semiconductor substrates on which epitaxial films of silicon or other materials are grown are preferably oxide free. An oxide layer, also referred to as a native oxide layer, typically forms when a clean surface of a semiconductor, and in particular, silicon, is exposed to air. Unlike purposefully grown oxides, native oxide is inconsistent and “dirty.” Oxide surfaces also form on the surfaces of other materials used in integrated device fabrication, for example, conductors such as copper. Native oxide and other impurities on semiconductor surfaces are typically removed prior to deposition using one or more wet cleaning steps. A common method for wet cleaning silicon wafers is performed as follows: (1) an RCA Standard Clean-1 (SC-1), which uses a mixture of aqueous ammonia and hydrogen peroxide at 70° C. to dissolve group I and II metals, and organic films; and (2) an RCA Standard Clean-2 (SC-2), which uses a mixture of hydrogen peroxide and hydrochloric acid at 70° C. to remove any remaining metals. An optional third step removes oxide chemically grown in the prior steps by dipping the wafer into hydrofluoric acid (HF), which leaves a somewhat protective hydrogen terminated surface. If this HF dip step is the last wet cleaning step, it is referred to as an HF last step.

Despite the wet cleaning, sub-monolayer amounts of native oxide may spontaneously regrow on a semiconductor surface, particularly when the substrates are stored for a prolonged period between the HF last dip and further processing, for example, epitaxial deposition. Depositing an epitaxial silicon layer over native oxide may result in polycrystalline rather than epitaxial growth. This polycrystalline growth is observable as wafer defects known as “halos.”

Native oxide is typically removed in situ within a deposition reactor prior to the deposition of an epitaxial layer. This process is also referred to as “cleaning.” One method of removing the oxide is baking the wafer under a hydrogen-containing gas, for example, hydrogen. The hydrogen is preferably contacted with both the front- and backsides of the wafer during the baking process. The difficulty in providing a hydrogen flow between the wafer and the susceptor on which the wafer is processed complicates cleaning the backside of a wafer, however, resulting in a wafer on which the oxide is incompletely cleaned from the backside. Consequently, DSP wafers often display halos on the backsides after epitaxial deposition, often in a grid pattern mirroring surface of the susceptor. These halos can cause localized temperature variations on the wafer resulting in process variations.

### SUMMARY OF THE INVENTION

Disclosed herein is an apparatus and method for processing both the front- and backsides of a substrate used in the fabrication of an integrated device.

In the illustrated embodiments, the substrate is loaded onto a first load platform in a reaction or process chamber. The first load platform is configured to permit cleaning or other process gases to contact both the front- and backsides of the wafer. In a preferred embodiment, the upper platform is defined by a plurality of support pins. The native oxide on both sides is baked-off under a hydrogen atmosphere. The wafer is then transferred to a second load platform, preferably in the same reaction chamber for further processing, for example, depositing epitaxial silicon.

Accordingly, an aspect of the disclosed invention provides an apparatus for processing a substrate used in the fabrication of an integrated device. In some embodiments, the apparatus comprises a reaction chamber within which is disposed a first load platform and a second load platform. The first load platform is configured to permit a process gas to contact the frontside and backside of a substrate loaded thereon, and the first load platform is mounted outside of the second load platform.

Another aspect provides a method for processing a substrate used in the fabrication of an integrated device. Some embodiments of the method comprise at least the steps of (1) loading the substrate on a first load platform; (2) contacting the substrate with a process gas; (3) transferring the substrate to a second load platform; and (4) processing the substrate on the second load platform. The first load platform is configured to permit a process gas to contact the frontside and backside of a substrate loaded thereon.

In some embodiments, the first load platform is higher than the second load platform, or is substantially directly above the second load platform. Preferably, the first load platform comprises a plurality of support pins, more preferably, three support pins. In some embodiments, the support pins are made from a material selected from the group consisting of quartz, silicon carbide, and silicon-carbide-coated graphite.

In some embodiments, the second load platform is a susceptor. In some embodiments, the reaction chamber is configured to deposit epitaxial silicon on a substrate loaded on the second load platform. In some embodiments, the apparatus comprises a heat source.

In a preferred embodiment, the substrate is a double-side polished single crystal silicon wafer. In some embodiments, the process gas cleans native oxide from the substrate. In some embodiments, the process gas is a hydrogen-containing gas. In some embodiments, the method further comprises heating the substrate.

### BRIEF DESCRIPTION OF THE DRAWINGS

FIG. 1A is a top plan view of an embodiment of the disclosed apparatus for treating both sides of a semiconductor substrate.

FIG. 1B is a partial side cross section of the embodiment illustrated in FIG. 1A in which a substrate is loaded on the upper load platform.

FIG. 1C is a partial side cross section of the embodiment illustrated in FIG. 1A in which a substrate loaded on the lower load platform.

FIG. 1D is a top plan view of another embodiment of the disclosed apparatus.

FIG. 2A and FIG. 2B are partial side cross sections of embodiments of the disclosed support pins with shoulders.

FIG. 3A is a top plan view of an embodiment of a ring-shaped upper load platform.

FIG. 3B is a side cross-section of the embodiment illustrated in FIG. 3A supporting a wafer.

FIG. 3C and FIG. 3D are side cross-sections of embodiments of upper load platforms with shoulders.

FIG. 3E is a side cross-section of an embodiment of an upper load platform with a frustoconical contact surface.

FIG. 3F is a side cross-section of an embodiment of an upper load platform with a curved contact surface.

FIG. 3G is a top plan view of an embodiment of a ring-shaped upper load platform with a reduced contact surface.

FIG. 3H is a top plan view of an embodiment of a square upper load platform.

FIG. 3I is a top plan view of an embodiment of a hexagonal upper load platform.

FIG. 4A is a top plan view of an embodiment of the disclosed apparatus for treating both sides of a semiconductor substrate with rotatable support pins.

FIG. 4B is a partial side cross section of the embodiment illustrated in FIG. 4A.

FIG. 4C is a side cross section of an embodiment of a pivoting support pin.

FIG. 4D is a side cross section of an embodiment of a retractable support pin.

FIG. 5 is a flowchart illustrating an embodiment of the disclosed method for processing both sides of a substrate using an apparatus with a fixed upper load platform.

FIG. 6 is a flowchart illustrating an embodiment of the disclosed method for processing both sides of a substrate using an apparatus with a movable upper load platform.

### DETAILED DESCRIPTION OF THE PREFERRED EMBODIMENTS

Disclosed herein is an apparatus and a process for contacting with a process gas both the front- and backsides of a substrate used in the fabrication of an integrated device. In some embodiments, the front- and backsides are contacted with the process gas simultaneously. In some embodiments, the disclosed process cleans native oxide from the front- and backsides of the substrate. Although some of the descriptions of the apparatus and method are made with reference to cleaning native oxide from both faces of a semiconductor wafer, those skilled in the art will recognize that the disclosed apparatus and method are useful for more generally contacting both faces of a semiconductor substrate with process gases. As used herein, the terms “side” and “face” are used interchangeably when referring to one of the frontside or backside of a semiconductor substrate or wafer.

In some embodiments, the substrate is any substrate that forms a native oxide, for example, silicon or silicon-germanium. A preferred substrate is a double-side polished (DSP) single crystal silicon wafer. Process gases used in the cleaning of native oxide are typically reducing gases, etching gases, or combinations thereof. A process gas suitable for cleaning native oxide is also referred to herein as a “cleaning gas.” A preferred cleaning gas is a hydrogen-containing gas. Examples of a preferred cleaning gas include hydrogen and a gas mixture comprising hydrogen, for example, a mixture comprising hydrogen and hydrogen chloride.

The illustrated apparatus comprises a reaction or process chamber equipped with a first load platform and a second load platform. The first load platform is configured to permit process gases, such as those used in the cleaning of native oxide from a substrate, access to both faces of a substrate loaded on the first load platform. The second load platform is configured to permit further processing of the substrate, preferably only on one face of the substrate. In some embodiments, the first load platform is positioned higher than the second load platform. In some embodiments, the first load platform is positioned substantially directly above the second load platform. In these embodiments, the first load platform is referred to as an “upper load platform,” and the second load platform is referred to as a “lower load platform.” Those skilled in the art will realize that other arrangements for the first and second load platforms are also possible.

One load platform is vertically adjacent to the other load platform, and preferably both load platforms are in the same reaction or process chamber. Thus, rapid sequential processing in the two positions is facilitated. Transfer between chambers is obviated and the substrate surface remains clean between steps. Furthermore, the two platforms share the same footprint and therefore conserve valuable clean room space.

A suitable reaction chamber is disclosed in U.S. Pat. No. 6,093,252, the disclosure of which is incorporated by reference. Those skilled in the art will recognize that any reaction chamber compatible with the disclosed apparatus may be used.

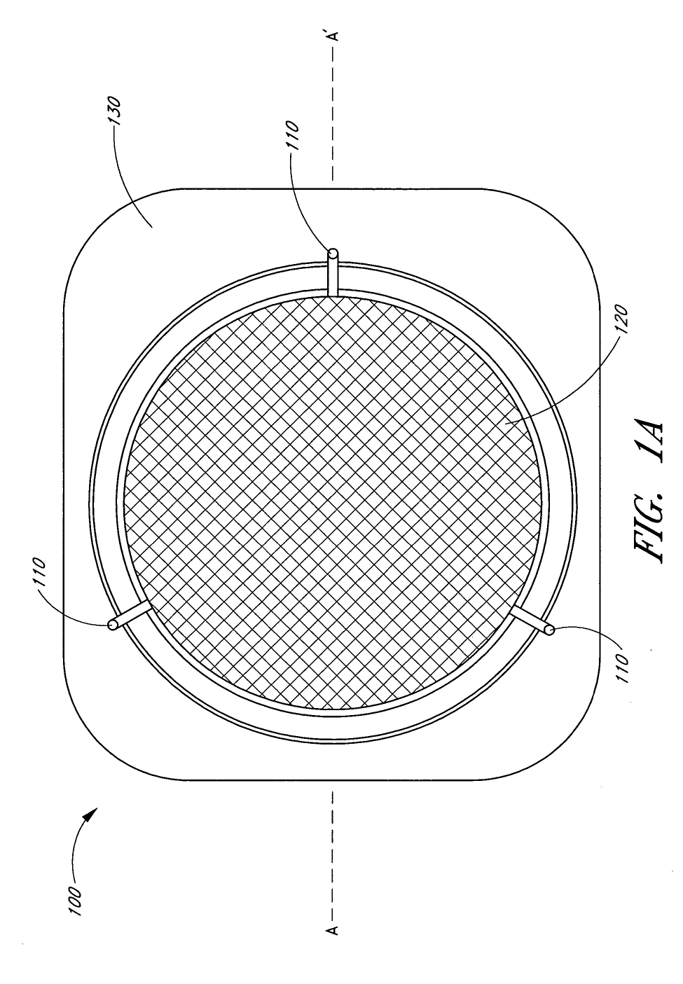

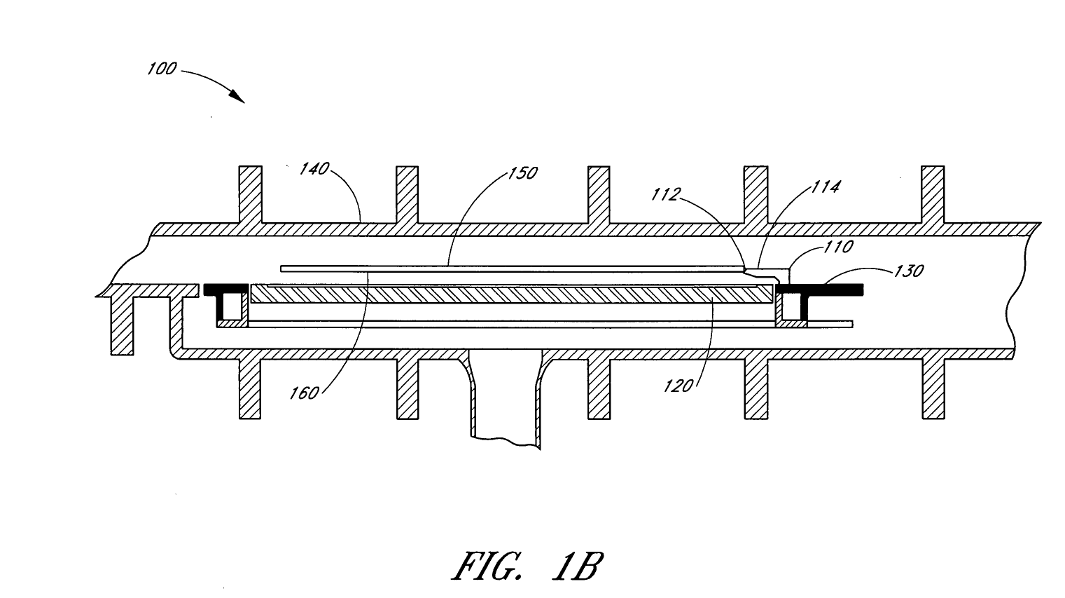

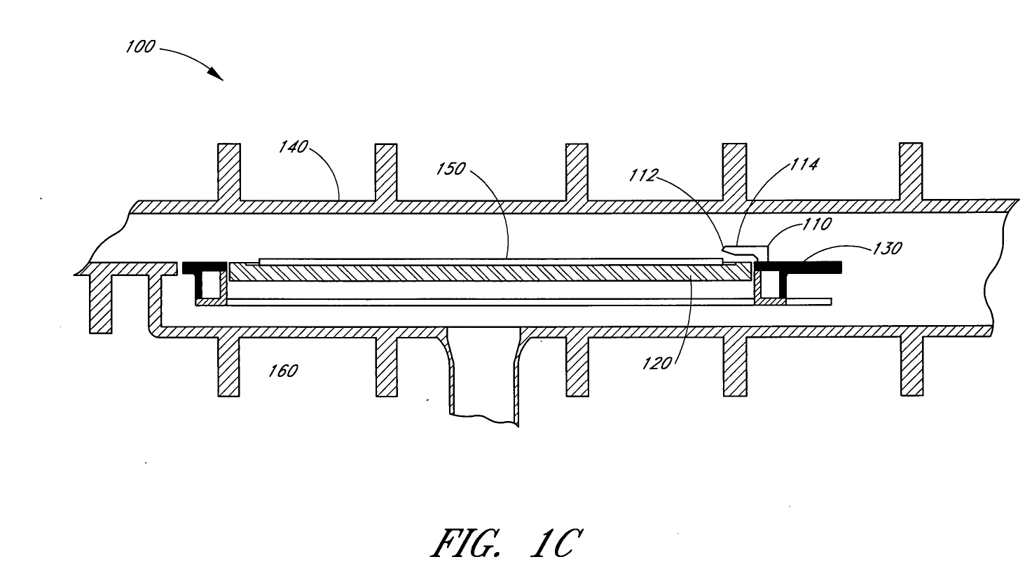

FIG. 1A is a top view of an embodiment of the disclosed apparatus 100 for treating the front- and backside of a semiconductor substrate with a process gas. FIG. 1B and FIG. 1C are partial side cross sections of an embodiment of the apparatus 100 in which the substrate is loaded on the first and second load platforms, respectively.

Referring to FIG. 1A, the apparatus 100 comprises a plurality of support pins 110, a susceptor 120, and a slip ring 130, all of which are disposed in a reaction chamber 140 (illustrated in FIG. 1B). The slip ring 130 is optional, and is designed to reduce heat loss from the edge of the substrate, thereby reducing crystallographic slip in the substrate. The support pins 110 collectively provide an upper load platform for a wafer 150 (illustrated in FIG. 1B). The support pins 110 are configured to provide peripheral or edge support for a wafer 150 mounted thereon. In the illustrated embodiment, the upper load platform is positioned substantially directly above the susceptor 120, which in the illustrated embodiment, serves as the lower load platform. The illustrated embodiment comprises three support pins 110. Other embodiments use different numbers of support pins 110, for example, two, four, five, or more. The support pins 110 are configured and adapted to provide sufficient clearance to allow the wafer 150 to be loaded onto and unloaded from the susceptor 120, as described in greater detail below. Unlike conventional “lift pins”, the illustrated support pins 110 are positioned independently of the susceptor 120; but in other arrangements, lift pins cans can be employed for the methods discussed herein. In the illustrated embodiment, a handling chamber or the like (not illustrated) is disposed in the A-direction and process gas flows in the A- to A′-direction. In some embodiments, the reaction chamber is equipped with one or more heating devices of any type known in the art, for example, radiant and/or resistive heaters.

In the following description, the substrate is transferred, moved, or positioned using any type of transfer device known in the art. In some embodiments, the transfer device is robotic, for example, a robot arm, and is equipped with a suitable end effector, for example, a Bernoulli wand, a quartz paddle, or a spatula type end-effector. Preferably the robot arm extends through an open gate valve between the process chamber and an adjacent handling chamber. In a preferred embodiment, the end effector is a Bernoulli wand, which holds a wafer by creating a low-pressure zone above the wafer. In some embodiments, the movements are performed using one transfer device. In another embodiment, the movements are performed using a plurality of transfer devices.

In the illustrated embodiment, the support pins 110 are substantially symmetrically disposed on the slip ring 130. In other embodiments, the support pins 110 are not symmetrically arranged. In other embodiments, the support pins 110 are mounted on another component of the reaction chamber, or to multiple components of the reaction chamber. For example, in some embodiments, the support pins are mounted on the floor of the reaction chamber 140. In other embodiments, the support pins are mounted on the walls of the reaction chamber, or suspended from the roof of the reaction chamber. In still another embodiment, the support pins are mounted on the susceptor 120. In some embodiments, the support pins 110 are designed and/or configured to reduce turbulence in the process gas stream. In some embodiments, the support pins 110 are designed and/or configured to reduce shadowing of the radiant heat source.

The susceptor 120 forms a lower load platform in the illustrated embodiment. The susceptor 120 is of any type known in the art, and is selected according to the particular process to be performed in the reactor. For example, the susceptor 120 may have a grid, for example, as described in U.S. Pat. No. 6,634,882, the disclosure of which is incorporated by reference.

FIG. 1B illustrates a partial side cross section of apparatus 100. Each of the illustrated support pins 110 (one shown) comprises a contact surface 112, upon which the wafer 150 rests. In the illustrated embodiment, the contact surface 112 is an angled surface, angled in such a way that the contact surfaces 112 of the support pins collectively face upwards and towards the interior of the upper load platform. This arrangement reduces the contact area between the contact surface 112 and wafer 150, and also helps to properly position the wafer 150 on the upper load platform. The support pins 110 are dimensioned to peripherally support a wafer 150, thereby forming an upper load platform over the susceptor 120. The height of the upper load platform above the susceptor 120 permits a sufficient amount of process gas to access the backside of the wafer 160, for example, to effectively remove oxide on the backside of the wafer 160. The height of the upper load platform will also depend on factors including the design of the support pins 110, the thickness of the end effector and wafer 150, and the dimensions of the transfer device. In some embodiments, the height of the wafer 150 over the susceptor 120 is preferably at least about 5 mm, more preferably at least about 10 mm most preferably at least about 15 mm, or particularly preferably, at least about 20 mm.

In the embodiment illustrated in FIG. 1B and FIG. 1C, the support pin 110 comprises a cantilever 114 that extends towards the center of the upper load platform. In the illustrated embodiment, the cantilever 114 provides both horizontal and vertical clearance for the transfer device to transfer the wafer 150 to and from the lower load platform, operations that move the wafer 150 between the support pins 110 and the susceptor. The height of the bottom of the cantilever 114 is sufficient to provide clearance for the wafer 150 and transfer device in the loading and unloading of the wafer onto and from the lower load platform.

In the embodiment illustrated in FIG. 1D, the upper load platform comprises support pins with at least two different shapes. The support pins 110′ comprise longer cantilevers 114′ than the cantilever 114 of support pin 110. Consequently, the gas stream flowing over a wafer 150 loaded on the lower load platform is less likely to be affected by the support pins 110′. Moreover, the longer cantilevers 114′ provide additional horizontal clearance for loading and unloading the wafer 150 onto and from the lower load platform.

The following describes an exemplary work path along which a wafer 150 is loaded onto and unloaded from the upper and lower load platforms, where the upper load platform is fixed with respect to the position of the lower load platform. It will be understood that FIGS. 1A and 1B have such a “fixed” relationship, although the susceptor can rotate in its position. Those skilled in the art will understand that alternative work paths are possible. Referring again to FIG. 1A, the wafer 150 is transferred using the transfer device into the reaction chamber, for example from a handling chamber (not illustrated). The wafer 150 is positioned at a predetermined height that is higher than the support pins 110. The wafer 150 is translated along axis A-A′ to a position substantially directly above the upper load platform formed by support pins 110. The wafer 150 is lowered to a height just above the upper load platform, then dropped or lowered thereon. This state is illustrated in FIG. 1B.

After the wafer 150 is processed on the upper load platform, the wafer 150 is unloaded from the upper load platform and loaded onto the lower load platform as follows. The transfer device picks-up the wafer 150 from the upper load platform and raises the wafer to a height higher than the support pins 110. The transfer device then retracts in the A-direction along axis A-A′ to a position clear of the support pins 110. The transfer device then adjusts the height of the wafer 150 such that the wafer 150 is between the bottom of the cantilever 114 and above the susceptor 120. The transfer device then extends along axis A-A′, positioning the wafer 150 above the susceptor 120. The height of the wafer is lowered to just above the susceptor 120, and the wafer 150 dropped thereon. This state is illustrated in FIG. 1C. After the wafer 150 is processed on the lower load platform, the process is reversed to unload the wafer 150.

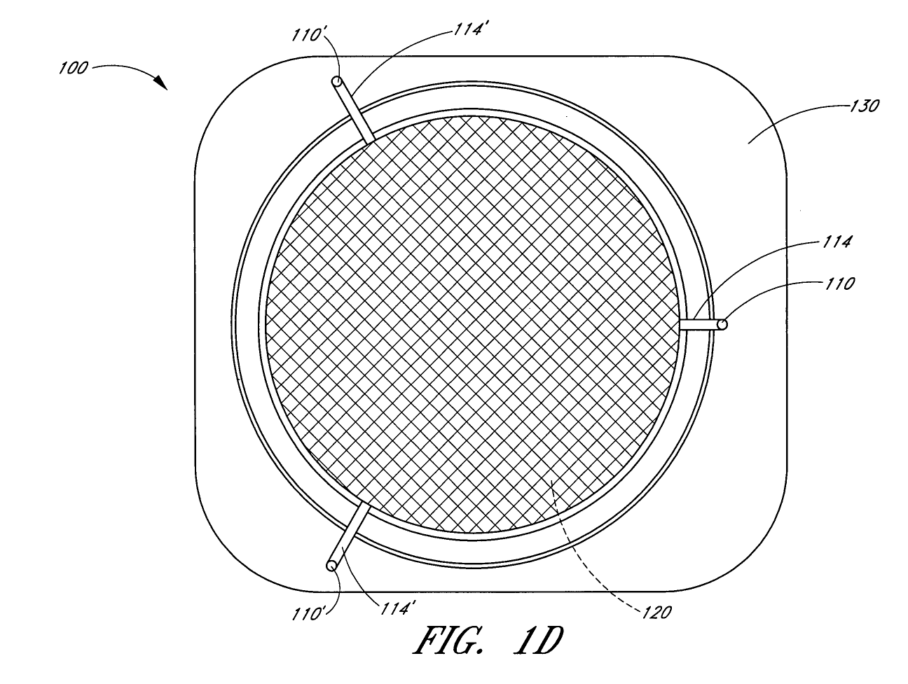

FIG. 2A illustrates a support pin 210, which is equipped with a shoulder 216 and a substantially horizontal contact surface 212. The shoulder 216 helps to maintain the position of the wafer 150 during processing on the upper load platform. In some embodiments, the shoulder 216 is adapted to engage the edge of a wafer 250. In the illustrated embodiment, the shoulder 216 is normal to the contact surface 212. In the embodiment of a support pin 210′ illustrated in FIG. 2B, the shoulder 216′ forms an obtuse angle with the substantially horizontal contact surface 212. In other embodiments, the profile of shoulder is curved, either concave upwards, or concave downwards, or has a combination of straight and curved segments. Preferably, the profile of the shoulder facilitates the loading and unloading of the wafer 250 onto and from the upper load platform, for example, by guiding the wafer 250 into position as it is lowered onto the upper load platform. In the embodiment illustrated in FIG. 2A, the shoulder 216 is lower than the top surface of the wafer 250. In the embodiment illustrated in FIG. 2B, the shoulder 216′ is about the same height as the wafer 250. Embodiments in which the shoulder is at about the same height or lower than the top of the wafer 250 are preferred because these configurations reduce turbulent gas flow across the surface of the wafer. In another embodiment, not illustrated, the shoulder is higher than the top of the wafer 250. In the illustrated embodiment, the support pins 210 and 210′ are mounted on a slip ring 130, and together form an upper support platform substantially directly above a susceptor 220.

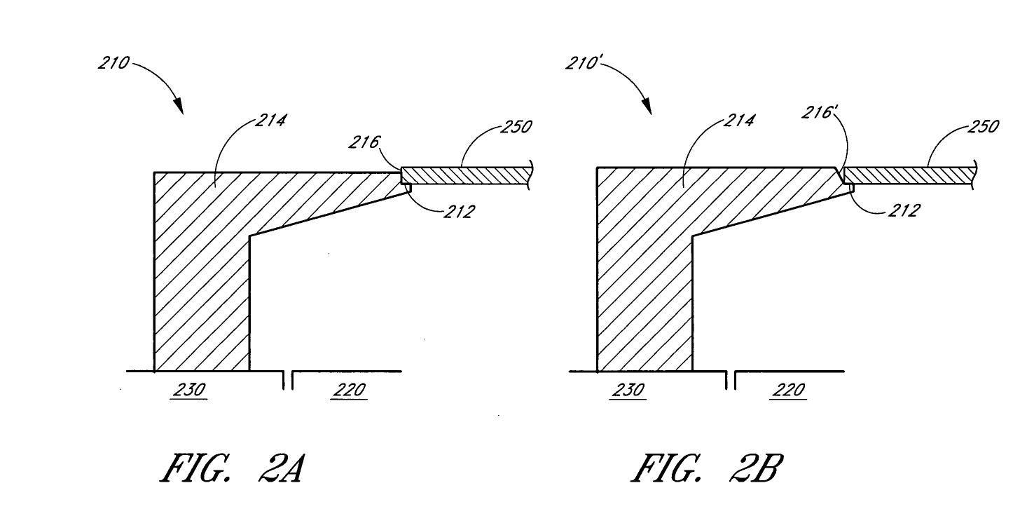

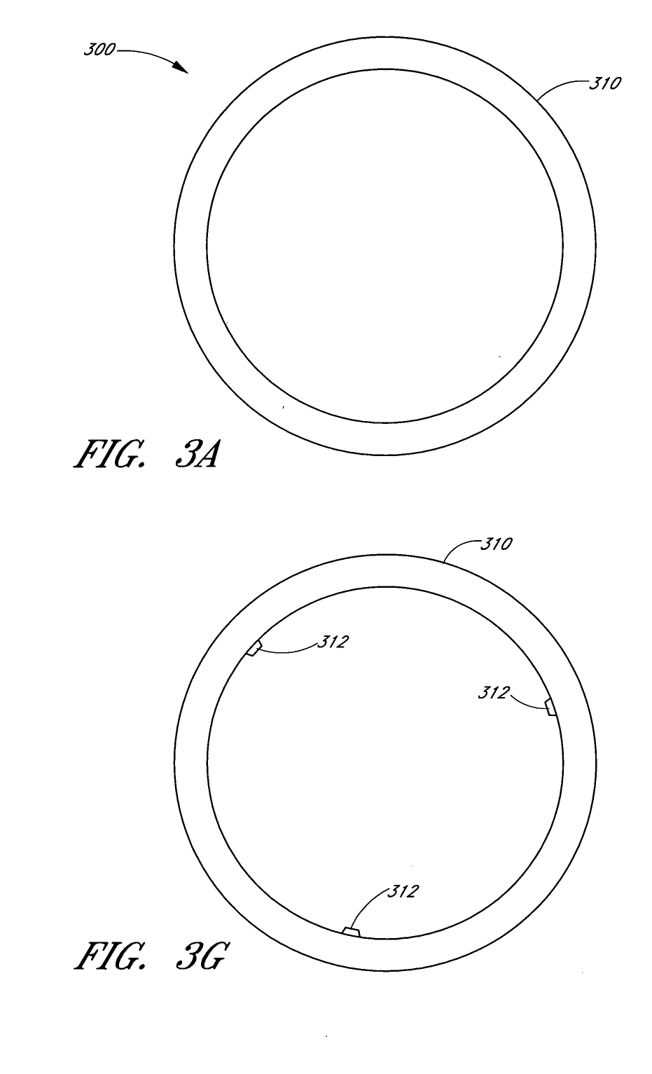

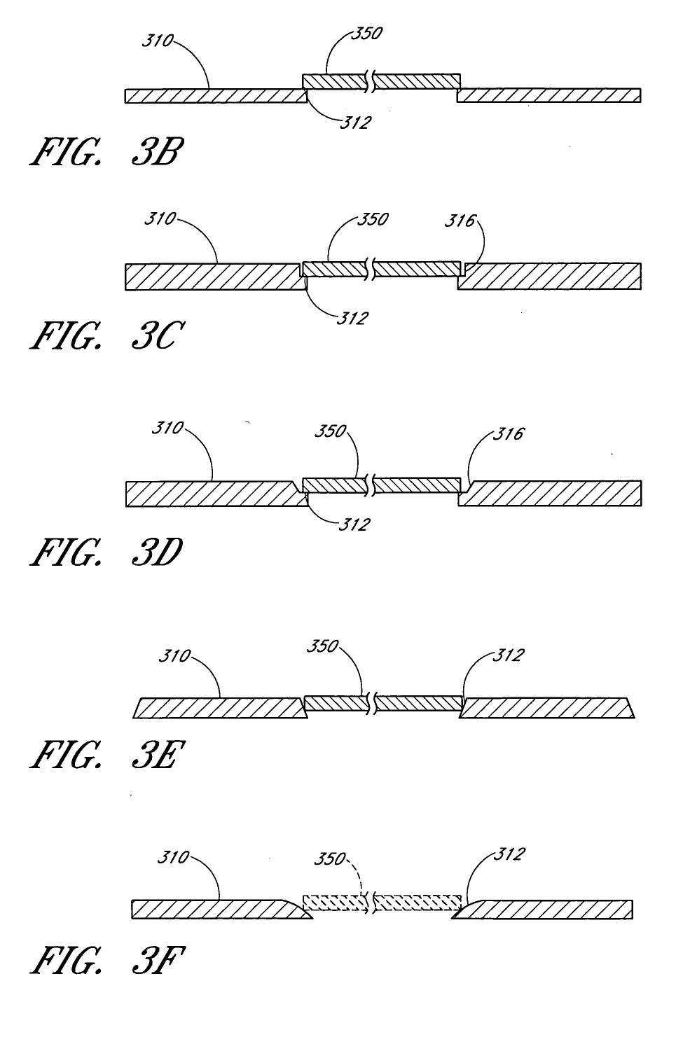

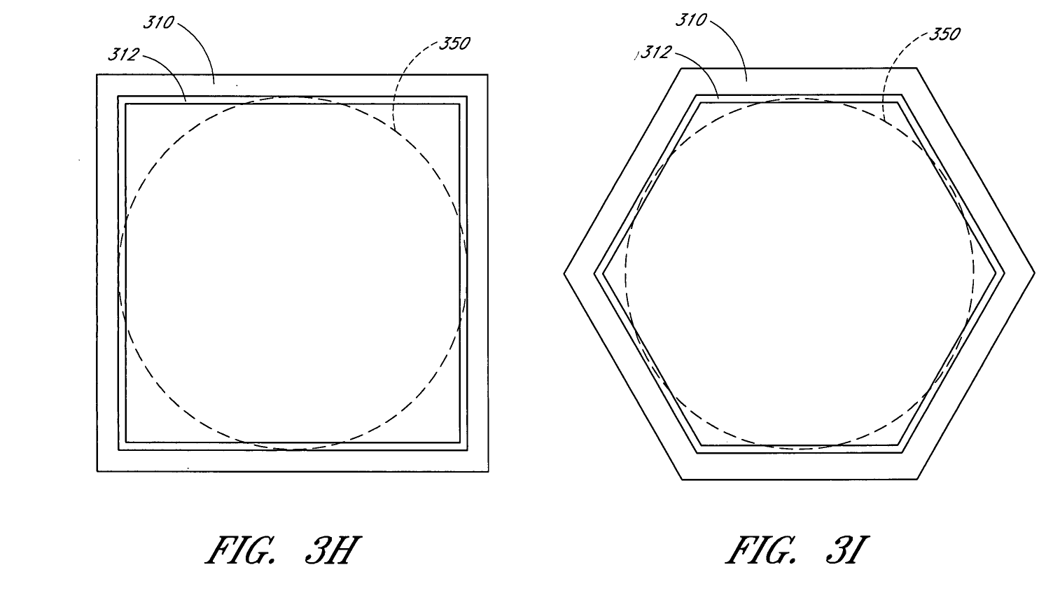

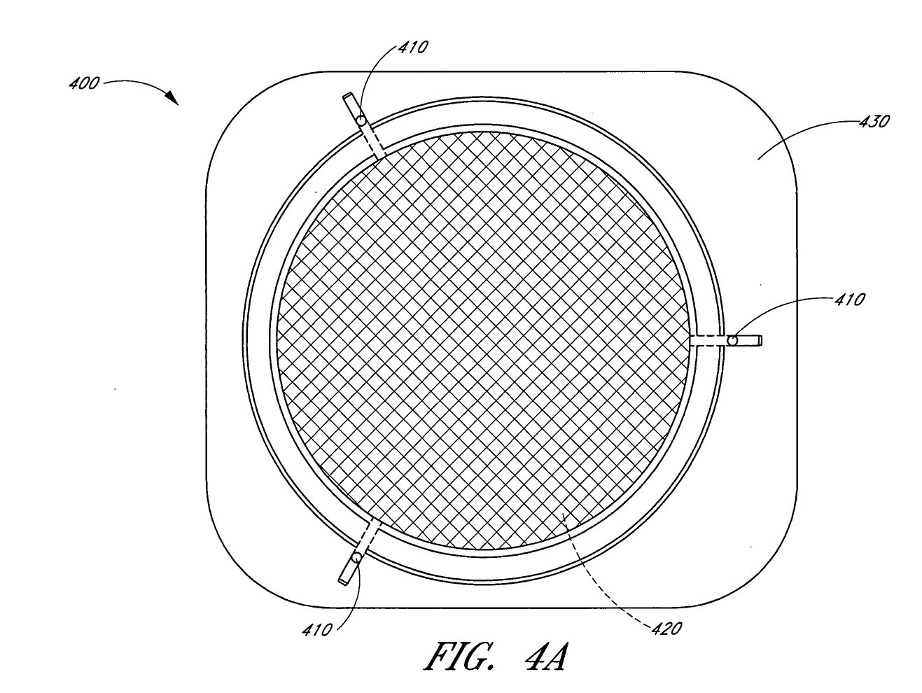

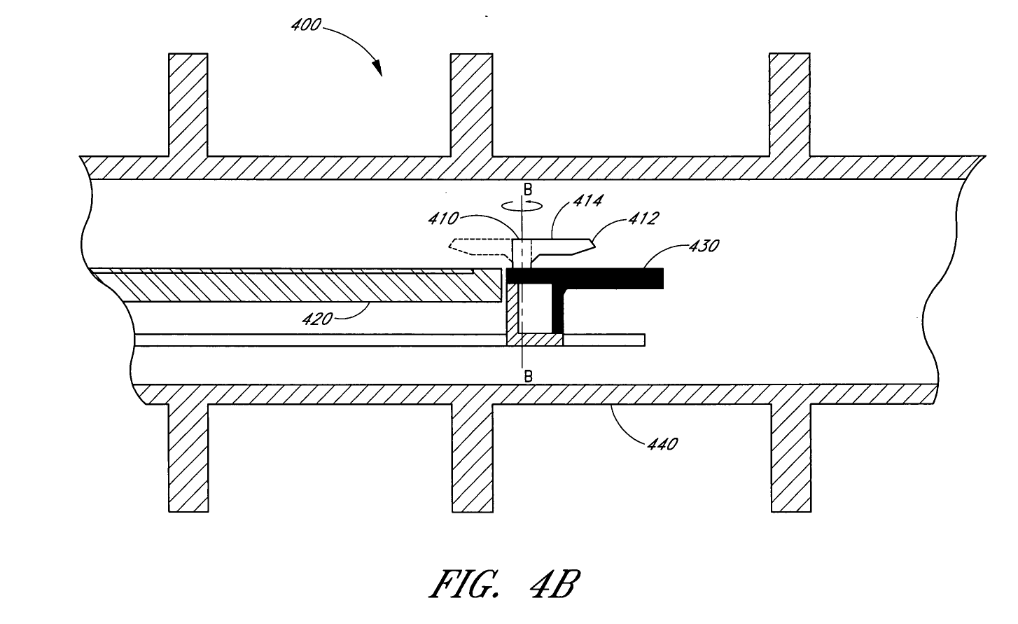

FIG. 3A illustrates an embodiment 300 in which the upper load platform is a ring 310 that supports substantially the entire edge of the wafer 350. In the illustrated embodiment, the ring 310 has a flat cross-section as illustrated in FIG. 3B. In other embodiments, the ring 310 comprises a shoulder 316 designed to position the wafer 350 on a contact surface 312 as shown in cross-section in FIG. 3C, in which the shoulder 316 is vertical, and FIG. 3D, in which the shoulder 316 is sloped. In another embodiment, the contact surface 312 of the ring 310 has a tapered cross-section as illustrated in FIG. 3E, thereby reducing the contact area between the contact surface 312 and the wafer 350. In the illustrated embodiment, the contact surface 312 is frustoconical. In another embodiment illustrated in FIG. 3F, the cross section of the contact surface 312 is curved.

FIG. 3G illustrates an embodiment in which portions of the contact surface 312 of the ring 310 are cut away to reduce contact with the edge of the wafer 350. FIG. 3H and FIG. 3I illustrate embodiments in which the ring 310 is not circular. The illustrated embodiments have square (FIG. 3H) and hexagonal rings (FIG. 3I) 310, although any shape that will support the wafer 350 may be used, for example, a horseshoe.

In some embodiments, the ring 310 is positioned within the reaction chamber using one or more fixed support members. In some embodiments, the ring 310 is substantially directly above the lower load platform. In another embodiment, the ring 310 is higher than, but not directly above the lower load platform, for example, “downstream” of lower load platform. In some embodiments, the ring 310 is secured to the slip ring. In another embodiment, the ring 310 is suspended above the lower load platform, for example from the upper wall (“roof”) of the reaction chamber, from the side rails, or from another structure within the reaction chamber. The supports are configured to permit loading and unloading a wafer 350 onto and from the upper and lower load platforms, while providing adequate process-gas access to a wafer loaded on either platform. In some embodiments the support members are situated “downstream” of the load platforms thereby reducing turbulence in the gas stream around the wafer 350.

In other embodiments, the ring 310 is not fixed. In some embodiments, the ring 310 is movable from a position substantially directly above the lower load platform to a position not directly above the lower load platform. For example, in some embodiments, the ring 310 is positioned substantially directly above the lower load platform while the wafer 350 is loaded on the ring 310 (the “supporting configuration”), and moved “downstream” of the lower load platform when the wafer 350 is loaded on the lower load platform (the “non-supporting configuration”). The ring 310 is moved using any means known in the art. In some embodiments, the ring 310 is pivotably supported on an axle and is pivoted around a vertical axis between the loaded and unloaded positions. In another embodiment, the ring 310 is supported on an arm that extends and retracts between the supporting and non-supporting configurations. In another embodiment, the ring 310 is supported on a rail or track.

The support pins or ring that comprise the upper load platform are made from any material compatible with the processing conditions, and which will not damage the wafer. Examples of suitable materials include quartz, silicon carbide, and silicon-carbide-coated graphite. Preferably, the surfaces of the upper load platform that contact the wafer do not damage the wafer, and in particular, the region inside the exclusion zone of the wafer. For example, in some embodiments, the support pins or ring are polished to reduce damage to the wafer.

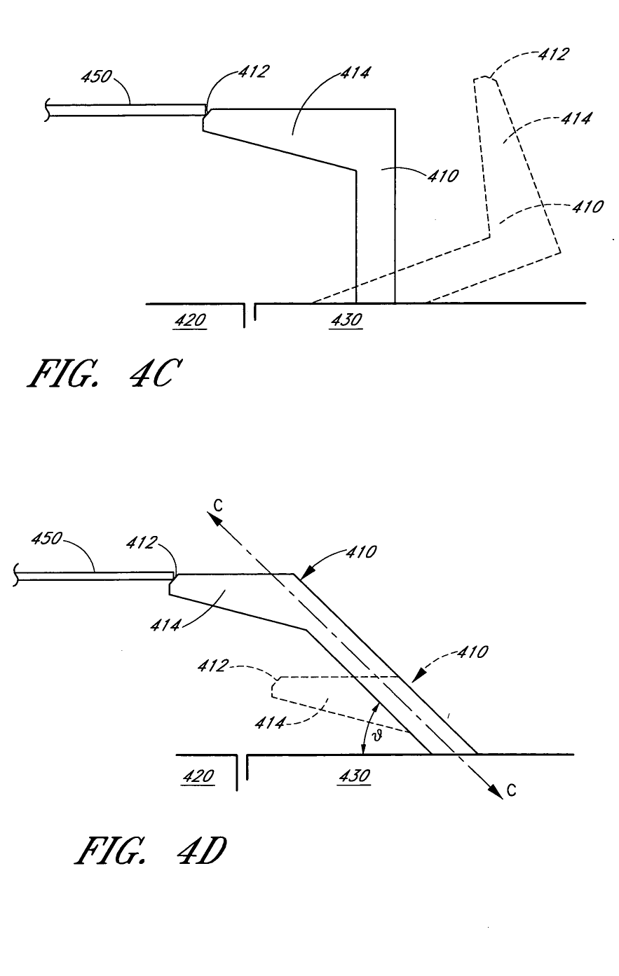

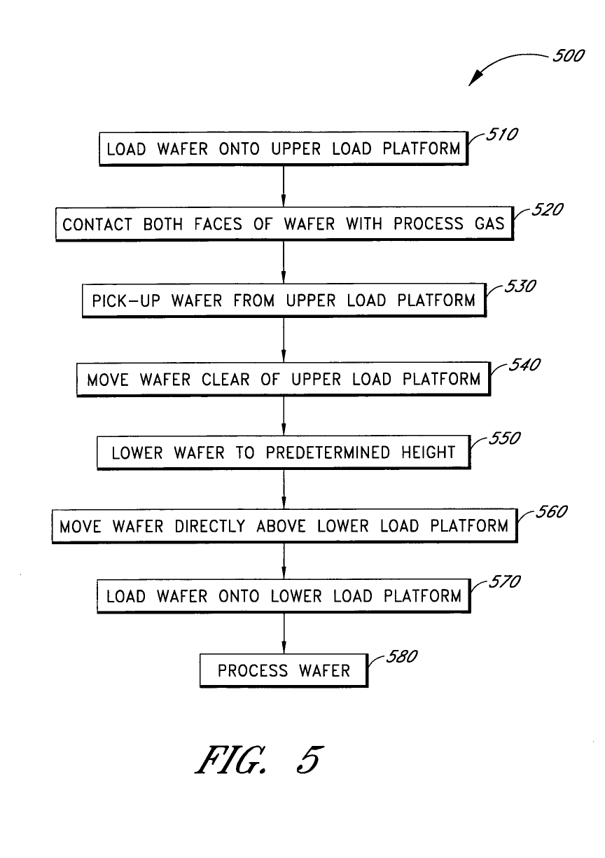

Similarly, in some embodiments comprising support pins, the upper load platform is not fixed. FIG. 4A is a top view and FIG. 4B a partial side cross section of an embodiment 400 of a rotatable support pin 410. The support pin 410 comprises cantilever 414 and a contact surface 412. In the illustrated embodiment, a plurality of support pins 410 are mounted on a slip ring 430, thereby forming an upper load platform substantially directly above a susceptor 420. In the illustrated embodiment, the support pin 410 is rotatable around axis B-B, thereby providing an upper load platform with a supporting configuration, illustrated in phantom, and a non-supporting configuration, illustrated with solid lines.

FIG. 4C illustrates another embodiment in which each support pin 410 pivots from a supporting configuration, illustrated with solid lines, to a non-supporting configuration, illustrated in phantom. In the illustrated embodiment, the support pin 410 pivots radially away from the susceptor 420 around an axis of rotation parallel to a tangent to the susceptor 420. In the illustrated embodiment, the axis of rotation is approximately at the same level as the surface of the slip ring 430, but in other embodiments, the axis is above or below the surface of the slip ring 430. In other embodiments, the axis is not parallel with a tangent to the susceptor 420, i.e., the support pin 410 pivots in different direction, for example, around a radial axis of the susceptor 420. In another embodiment (not illustrated), the support pins are configured to move radially with respect to the susceptor from a supporting configuration to a non-supporting configuration.

The support pins 410 are rotated, pivoted, or moved using any means known in the art, for example, using a motor, solenoid, or a pneumatic or hydraulic actuator. In these embodiments, the support pins may be configured to be independently movable from the supporting to the non-supporting configurations, or to move in unison between these configurations. In some embodiments, the movement between the supporting and non-supporting configurations is automated, for example, under microprocessor or computer control, and is coordinated with the robotic transfer device.

FIG. 4D illustrates an embodiment of a support pin 410 in which the support pin 410 forms an angle θ with the slip ring 430, providing additional clearance for loading the wafer on the lower load platform. In the illustrated embodiment, the support pin 410 extends along axis C-C to provide a supporting configuration (solid lines), and retracts to a non-supporting configuration (phantom), in which the pin 410 is retracted. In some embodiments, the support pin 410 retracts into a recess in the slip ring 430, thereby reducing turbulence in the gas flow. The angle θ will depend on factors including the length of the cantilever 414, the height of the support pin 410, and the distance between the support pin 410 and the susceptor 420, and is readily ascertained by those skilled in the art.

In the embodiments illustrated in FIGS. 4A-D, the support pins 410 possess a horizontal motion component, which permits the transfer device to transfer the wafer from the upper load platform to the lower load platform or vice versa without retraction and extension (e.g., translation) of the wafer transfer robot. In another embodiment (not illustrated), the support pins are configured to move upwards and downwards from a supporting configuration to a non-supporting configuration, which also permits the transfer device to transfer the wafer from the upper load platform to the lower load platform without retraction and extension. This last embodiment includes the use of wafer lift pins known in the art for the method described herein.

In contrast to the embodiments illustrated in FIGS. 4A-D, in which the upper load platform is changed from a supporting position to a non-supporting position, in other embodiments, the entire upper load platform is translated or rotated from a supporting position to a non-supporting position. These embodiments are particularly suited to those embodiments in which the upper load platform is a ring or portion thereof, or otherwise monolithic, for example, the support rings illustrated in FIGS. 3A-G. In embodiments in which the supporting position of the upper load platform is substantially directly above the lower load platform, the transfer device can transfer the wafer from the upper load platform to the lower load platform without retraction and extension. With the substrate loaded on the upper load platform in the supporting position, the transfer device picks-up the wafer, the upper load platform is moved to the non-supporting position, and the transfer device lowers the wafer onto the lower load platform.

In the illustrated embodiments, the first support platform is positioned substantially directly above the susceptor, with serves as the second load platform. This configuration provides a reaction chamber with a first load platform and a second load platform with little or no increase in the size of the reaction chamber compared to a reaction chamber without a first load platform. In other embodiments, the first load platform is positioned in another location in the reaction chamber, for example, in front of the second load platform, behind the second load platform, beside the second load platform, or below the second load platform.

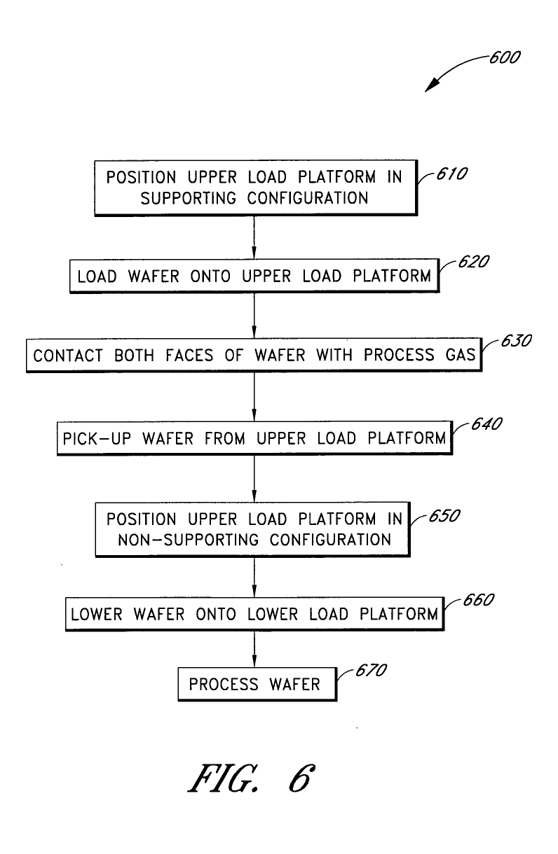

An embodiment 500 of a method for contacting the front- and backsides of a wafer with a process gas is illustrated in FIG. 5, with reference to the apparatus illustrated in FIG. 1A, FIG. 1B, and FIG. 1C in which the upper load platform is fixed.

In step 510, a wafer 150 is loaded onto an upper load platform, which comprises support pins 110, as illustrated in FIG. 1B. In step 520, both faces of the wafer 140 are contacted with a process gas. In step 530, the wafer 150 is picked-up from the upper load platform using a transfer device. In step 540, the transfer device is used to move the wafer 150 to a position clear of the support pins 110, for example, by horizontal retraction. In step 550, the height of the wafer 150 is adjusted to a position below the upper load platform and above the lower load platform, for example, by lowering the robot arm. In step 560, the wafer is positioned substantially directly above the lower load platform using the transfer device, for example, by extending the robot arm. In step 570, the wafer is loaded onto a susceptor 120, which serves as a lower load platform, as illustrated in FIG. 1C. In step 580, the frontside of the wafer 150 is further processed, with the susceptor 120 substantially shielding the backside of the wafer from process gases. Suitable processing steps are well known in the art, and include, for example, chemical vapor deposition and atomic layer deposition.

In some embodiments, the wafer 150 is moved using a transfer device, for example, a robot arm, which is programmed with at least four predetermined vertical positions. As will be apparent to one skilled in the art, these vertical positions refer to the position of the end effector used in handling the wafer rather than the entire transfer device. (1) A position clear of the top of the support pins 110 at which the robot arm extends and retracts for transferring the wafer 150 to and from the upper load platform. This position is referred to herein as “height 1.” (2) A position directly above the upper load platform from which the wafer is dropped 150 onto and lifted from the upper load platform. This position is referred to herein as “height 2.” Height 2 is typically lower than height 1, but in some embodiments, is the same as height 1. (3) A position below the upper load platform and above the lower load platform at which the robot arm extends and retracts for transferring the wafer 150 to and from the lower load platform 120. This position is referred to herein as “height 3.” (4) A position directly above the lower load platform from which the wafer 150 is dropped onto and lifted from the lower load platform 120. This position is referred to herein as “height 4.” Height 4 is typically lower than height 3, but in some embodiments, is the same as height 3.

In step 510, the wafer 150 is loaded onto the upper load platform, for example, from a handling chamber, using any type of transfer device known in the art, for example, a Bernoulli wand, a quartz paddle, or a spatula type end-effector. This state is illustrated in FIG. 1B. In this step, the wafer 150 is transferred to a position substantially directly above the upper load platform at height 1, moved to height 2, and dropped onto the upper load platform. In some embodiments, the transfer device is then retracted to a neutral position.

In step 520, a process gas is introduced into the reaction chamber 140, thereby contacting both the front- and backsides of the wafer 150. In some embodiments, native oxide is cleaned from a wafer 150 by contacting both the front- and backsides of the wafer 150 with a cleaning gas for a time and at a temperature sufficient to clean the oxide. In some embodiments, the cleaning gas is a hydrogen-containing gas, for example, hydrogen or a gas mixture that comprises hydrogen. In some embodiments, native oxide is cleaned from a silicon wafer using a hydrogen-containing gas at a temperature of at least about 700° C. An example of suitable conditions for cleaning native oxide is provided in U.S. Patent Publication No. 2003/0036268 A1, the disclosure of which is incorporated by reference. In some embodiments, the pressure of the hydrogen-containing gas is about atmospheric pressure. In other embodiments, the pressure of the hydrogen-containing gas is below atmospheric pressure. Optionally, the wafer 150 is allowed to cool after cleaning.

In step 530, the wafer 150 is picked-up from the upper load platform using any means known in the art. In some embodiments, the wafer 150 is picked-up using the same transfer device used in step 510. In the embodiment illustrated FIG. 1A, the transfer device at height 1 extends from the A-direction. The transfer device then moves to height 2 and picks up the wafer.

In step 540, the transfer device moves to height 1, then moves the wafer to a position clear of upper load platform. In the embodiment illustrated in FIG. 1A, the transfer device retracts along axis A-A′ in the A-direction until the wafer 150 is clear of the support pins 110, that is, is not directly above any of the support pins 110. Note that the wafer 150 may overlap the susceptor 120 in this position.

In step 550, the wafer 150 is adjusted to height 3, which is a height suitable for loading the wafer onto the lower load platform, while avoiding interference from the upper load platform. This height will depend on the shapes of the support pins 110, the thickness of the wafer 150, and the dimensions of the transfer device. In the embodiment illustrated in FIGS. 1A-C, height 3 is a height between the bottoms of the cantilevers 114 and the top of the susceptor 120.

In step 560, the transfer device moves the wafer 150 into a position suitable for loading the wafer 150 onto the lower load platform. In the embodiment illustrated in FIGS. 1A-C, the transfer device extends along axis A-A′, positioning the wafer 150 substantially directly above the susceptor 120.

In step 570, the robot arm is moved to height 4, and the wafer 150 is loaded onto the second load platform, which in the illustrated embodiment, is the susceptor 120. This state is illustrated in FIG. 1C. In some embodiments, the transfer device is then retracted to a neutral position.

In step 580, the wafer 150 is further processed. In some embodiments, the processing is the epitaxial deposition of silicon. The deposition may be performed using any method known in the art, for example, using chemical vapor deposition (CVD), plasma enhanced CVD (PECVD), atomic layer deposition (ALD), or radical enhanced ALD (REALD). Preferably processing is conducted only on the frontside or upper surface of the wafer 150.

FIG. 6 illustrates another embodiment 600 of a method for contacting the front- and backsides of a wafer with a process gas in an apparatus in which the upper load platform is not fixed, but instead has a supporting configuration in which the upper load platform is positioned substantially directly above the lower load platform, and a non-supporting configuration. Examples of such apparatus include embodiments of the apparatus illustrated in FIGS. 4A-D and FIGS. 3A-I. The following description of the method 600 is made with reference to the embodiments illustrated in FIGS. 4A-B. In some embodiments, the transfer device can have the four predetermined heights as described above in reference to the embodiment illustrated in FIG. 5, but the ability to horizontally move elements defining the upper load platform enables elimination of extension and retraction motions, and possibly also eliminates one or two of the vertical positions for the robot.

In step 610, the upper load platform is positioned in a supporting configuration. In step 620, a wafer is loaded onto the upper load platform. In step 630, both faces of the wafer are contacted with a process gas. In step 640, the wafer is picked-up from the upper load platform using a transfer device. In step 650, the upper load platform is positioned in a non-supporting configuration. In step 660, the wafer is lowered onto the lower load platform. In step 670, the wafer is further processed.

In step 610, the upper load platform is positioned in a supporting configuration. In the embodiment illustrated in FIGS. 4A-B, the support pins 410 are rotated into the supporting configuration.

In step 620, a wafer is loaded onto the upper load platform. A suitable method for loading the wafer is described above.

In step 630, a process gas is introduced into the reaction chamber, thereby contacting both the front- and backsides of the wafer. Suitable conditions for cleaning native oxide in this step are described above.

In step 640, the wafer is picked-up from the upper load platform using any method known in the art. In some embodiments, the wafer is picked-up using the same device used in step 620.

In step 650, the upper load platform is positioned in a non-supporting configuration. In the embodiment illustrated in FIG. 4A and FIG. 4B, the support pins 410 are rotated from the supporting configuration to the non-supporting configuration.

In step 660, the wafer is lowered onto the lower load platform, then released by the transfer device.

In step 670, the wafer is further processed, as described above.

Those skilled in the art will realize that the methods illustrated in FIG. 5 and FIG. 6 may be performed using the apparatus described herein. For example, the method illustrated in FIG. 5 is applicable to embodiments of the apparatus illustrated in FIGS. 3A-I in which the support ring is fixed. The method illustrated in FIG. 6 is also practiced using a reactor equipped with a susceptor equipped with wafer lift pins.

In the illustrated embodiments, the apparatus is installed within a reaction chamber that is configured for epitaxial deposition. Those skilled in the art will realize that the apparatus may also be installed in any type of suitable reaction chamber. The disclosed process is particularly suited for sequentially conducting two types of processes: (1) a two-side process for a substrate; and (2) a single-sided process for a substrate, and in particular, a process in which process gases can leak to the backside of the substrate, for example, when using a grid susceptor. In some embodiments, the apparatus is installed in a reactor purpose-built for cleaning oxide, for example, a module for a cluster tool. In this embodiment, the reaction chamber need not comprise a second load platform.

### EXAMPLE

An Epsilon® 3000 Epitaxial Reactor available from ASM America, Inc. of Phoenix, Ariz. is equipped with a silicon carbide coated graphite susceptor with a deep grid pattern, as described in U.S. Pat. No. 6,634,882, the disclosure of which is incorporated by reference. The reactor is modified to include three quartz support pins as illustrated in FIGS. 1A-C, which together form an upper load platform about 15 mm above the susceptor. Two 300-mm <100> CZ double-side polished silicon wafers (Wafer A and Wafer B) are cleaned using RCA SC-1 and SC-2, with an HF last dip. The wafers are loaded into a load lock mounted to the reactor.

Wafer A is transferred from the load lock to the upper load platform using a Bernoulli wand. The native oxide is baked off under 1 atmosphere of hydrogen at 800° C. for about 2 minutes. The wafer is picked-up from the upper load platform using the Bernoulli wand, then the Bernoulli wand retracted to a position in which the wafer is not directly above any part of the quartz support pins. The wafer is lowered to a height about 5 mm higher than the susceptor, and the Bernoulli wand extended to position the wafer substantially directly above the susceptor, whereupon the wafer is lowered and loaded onto the susceptor. A 1-μm thick layer of epitaxial silicon is deposited on the wafer by reduced pressure CVD (RPCVD) using trichlorosilane (30 sccm at 250 torr) at 1100° C. for about 2 minutes. The wafer is transferred back into the load lock.

Wafer B is transferred from the load lock directly onto the susceptor. The native oxide is baked off and a 3-μm thick layer of epitaxial silicon layer deposited as described above. The wafer is transferred back into the load lock. On examination, the backside of Wafer A is clean, while the backside of Wafer B has a halo of polysilicon in the grid pattern of the susceptor.

The embodiments illustrated and described above are provided only as examples of certain preferred embodiments. Various changes and modifications can be made to the embodiments presented herein by those skilled in the art without departure from the spirit and scope of the disclosure, which is limited only by the appended claims.

1. An apparatus for processing a substrate comprising a frontside and a backside used in the fabrication of an integrated device, the apparatus comprising a reaction chamber, a first load platform, and a second load platform, wherein:
the first load platform and the second load platform are disposed within the reaction chamber;
the first load platform is configured to permit a process gas to contact both the frontside and backside of a substrate loaded on the first load platform; and
the first load platform is mounted outside of the second load platform.

2. The apparatus of claim 1, wherein the first load platform is higher than the second load platform.

3. The apparatus of claim 2, wherein the first load platform is substantially directly above the second load platform.

4. The apparatus of claim 2, wherein the first load platform is at least about 10 mm higher than the second load platform.

5. The apparatus of claim 1, wherein the first load platform comprises a plurality of support pins.

6. The apparatus of claim 5, wherein the first load platform comprises three support pins.

7. The apparatus of claim 5, wherein the support pins are made from a material selected from the group consisting of quartz, silicon carbide, and silicon-carbide-coated graphite.

8. The apparatus of claim 1, wherein the second load platform is a susceptor.

9. The apparatus of claim 8, further comprising a heat source.

10. The apparatus of claim 8, wherein the reaction chamber is configured to deposit epitaxial silicon on a substrate loaded on the second load platform.

11. The apparatus of claim 1, further comprising a heat source.

12. A method for processing a substrate used in the fabrication of an integrated device, the method comprising:
loading the substrate comprising a frontside and a backside on a first load platform in a process chamber;
contacting the frontside and the backside of the substrate with a process gas while on the first load platform;
transferring the substrate to a second load platform in the process chamber; and
further processing the substrate on the second load platform.

13. The method of claim 12, wherein transferring the substrate to a second load platform comprises:
picking up the substrate using a transfer device;
moving the substrate clear of the upper load platform;
lowering the substrate to a predetermined height between the upper load platform and the lower load platform;
moving the substrate substantially directly above the lower load platform; and
loading the substrate onto the lower load platform.

14. The method of claim 13, wherein moving the substrate clear of the upper load platform comprises lifting the wafer from the upper load platform, retracting the wafer, and lowering the wafer to a vertical position between the upper load platform and the lower load platform.

15. The method of claim 12, wherein transferring the substrate to a second load platform comprises:
picking up the substrate using a transfer device;
positioning the upper load platform in a non-supporting configuration; and
lowering the substrate onto the lower load platform.

16. The method of claim 15, wherein positioning the upper load platform in a non-supporting configuration comprises horizontally moving support elements.

17. The method of claim 16, wherein the support elements comprise movable support pins.

18. The method of claim 17, wherein moving the support elements comprises rotating the support pins horizontally outwardly.

19. The method of claim 18, wherein rotating the support elements comprises rotating the support pins about an axis parallel to a tangent to the substrate.

20. The method of claim 17, wherein moving the support elements comprises retracting the support pins linearly with a horizontal movement component.

21. The method of claim 20, wherein retracting the pins further includes a vertical movement component.

22. The method of claim 12, wherein the substrate is a double-side polished single crystal silicon wafer.

23. The method of claim 12, wherein contacting the substrate with a process gas cleans native oxide from the frontside and the backside of the substrate.

24. The method of claim 23, wherein the process gas is a reducing gas.

25. The method of claim 23, wherein contacting further comprises heating the substrate.

26. The method of claim 12, wherein further processing comprises depositing a layer on the substrate.

27. The method of claim 26, wherein further processing comprises depositing the layer substantially only on the frontside of the substrate.

28. A method of processing a semiconductor substrate, comprising:
loading a substrate onto a first platform
performing a first process on the substrate while loaded upon the first platform, wherein the first process comprises upper and lower sides of the substrate to a first process gas;
moving the substrate from the first platform to a vertically adjacent second platform; and
performing a second process upon the substrate while on the second platform, wherein the second process comprises exposing substantially only the first side of the wafer to a second process gas.

29. The method of claim 28, wherein the first process comprises oxide reduction.

30. The method of claim 29, wherein the second process comprises epitaxial deposition.

31. The method of claim 28, wherein the first and second platforms are both within a single process chamber.

32. The method of claim 31, wherein moving the substrate comprises employing a robot arm extending from outside the process chamber.

33. The method of claim 28, wherein moving comprises horizontally moving support pins radially outwardly to allow substrate movement vertically from the first platform to the second platform.

34. The method of claim 28, wherein moving the substrate comprises at least one robotic retraction and extension while support elements defining the first platform remain fixed with respect to a position of the second platform.

35. A method of processing a semiconductor wafer comprising:
conducting a native oxide clean on the semiconductor wafer within a process chamber, wherein the oxide clean removes native oxide from upper and lower surfaces of the semiconductor wafer;
loading the wafer onto a susceptor, wherein a lower surface of the wafer is supported upon the susceptor; and
depositing a layer on the wafer upper surface while the wafer is supported upon the susceptor.

36. The method of claim 35, wherein conducting the native oxide clean and depositing the layer are conducted in situ within a single process chamber.

37. The method of claim 35, wherein conducting the native oxide clean comprises supporting the wafer upon an upper platform vertically spaced above the susceptor.
